(19) United States
(12) Patent Application Publication
(10) Pub. No.: US 2008/0121521 A1
(43) Pub. Date: May 29, 2008

(54) Plasma sputtering target assembly and manufacturing method therefor

(75) Inventors: Hsiang-Hsien Chung, Taipei (TW); Wen-Kuang Tsao, Taipei (TW); Hung-Yi Hsu, Taipei (TW); Chien-Yu Chen, Taipei (TW)

Correspondence Address: REED SMITH LLP, Suite 1400, 3110 Fairview Park Drive, Falls Church, VA, 22042, US

(73) Assignee: Chunghwa Picture Tubes, Ltd.

(21) Appl. No.: 11/504,075

(22) Filed: Aug. 15, 2006

(51) Int. Cl. C23C 14/00

(52) U.S. Cl. 204/298.12

(57) ABSTRACT

A plasma sputtering target assembly and a method therefor are provided. The sputtering target assembly includes a target, a bonding layer having a plurality of particles and having a first side bonded with the target and second side, and a backplate bonded with the second side of the bonding layer. The particles are being provided when the backplate is heated. Alternatively, a plurality of protrusions is formed on the backplate and the bonding layer is larger than or equal to the protrusions in altitude. Since the bonding layer has a composition and sputter yield of the part different from that of the target, in sputtering, the bonding layer is made exposed to plasma and thus an exceptional discharging phenomenon is caused when the target is struck through. By detecting the phenomenon, whether the target is almost over-sputtered may be forecasted and the backplate may be prevented from being struck through.

### BACKGROUND OF THE INVENTION

1. Field of the Invention

The present invention relates to a plasma sputtering target assembly and a manufacturing method therefor. More particularly, the present invention relates to a sputtering target assembly and a manufacturing method therefor where particles are provided on a side of a bonding layer of a sputtering target nearer a target in the assembly or a plurality of protrusions is formed on a backplate in the assembly.

2. Descriptions of the Related Art

Conventionally, a periodical visual inspection is generally relied upon in prevention of a target being over-sputtered in a sputtering process. However, this method is labor-consuming and may sometimes cause the target to be stuck through, making it unqualified for use in a proper sputtering process. Another method is to insert a bladder between a backplate and the target. This method may efficiently prevent the target from being over-sputtered since the bladder will burst in a vacuum environment and cause the sputtering process to be broken off before the over-sputtering phenomenon occurs. However, when the bladder bursts, a suddenly increased pressure and thus an abruptly elevated temperature occur, causing a chamber for the sputtering process to be deformed or damaged. In another method, a dielectric layer is inserted between the target and the backplate. When this dielectric layer is exposed to plasma, charges will accumulate on the dielectric layer since the dielectric layer is not electrically conductive. As a result, an exceptional discharging phenomenon is brought about. Then, optical and electromagnetic signals involved with the exceptional discharging are used as a reference for stopping provision of the supplied power for the sputtering process. However, since the backplate itself may conduct a current to the target and cool the target and since the dielectric layer does not provide electrical and thermal conductivities as good as those of a metal backplate, an adverse effect is arisen with respect to the thus formed thin film. That is, the dielectric layer provided between the backplate and the target may bring an adverse effect to cooling efficiency and conductivity between the backplate and the target, correspondingly having an influence on stability of the conducted process.

### SUMMARY OF THE INVENTION

It is, therefore, an object of the present invention to provide a plasma sputtering target assembly through which a backplate therein may be prevented from being stuck through and thus being over-sputtered.

To achieve the above object, the plasma sputtering target assembly disclosed in the present invention comprises a target, a bonding layer having a plurality of particles and having a first side bonded with the target and a second side, and a backplate bonded with the second side of the bonding layer.

To achieve the above object, another plasma sputtering target assembly disclosed in the present invention comprises a target, a bonding layer having a first side bonded with the target and a second side, and a backplate having a plurality of particles bonded with the second side of the bonding layer.

To achieve the above object, the present invention also discloses a manufacturing method of the plasma sputtering target assembly, comprising the steps of providing a target, providing a bonding layer having a plurality of particles and having a first side bonded with the target and second side; providing a backplate which has a plurality of protrusions integrated with the backplate and the protrusions are not greater than the bonding layer in altitude; and proceeding a bonding process for bonding the backplate with the bonding layer so as to bond the backplate and the second side of the bonding layer.

The bonding layer is provided on between the backplate and the target, wherein particles are provided on a side of the bonding layer nearer the target or a plurality of protrusions is formed and integrated with the backplate. As such, the target may be exposed to plasma and an exceptional discharging phenomenon may be caused before over-sputtering occurs on the target. By detecting the discharging phenomenon, a power supplied for the sputtering process may be ceased and thus the backplate may be prevented from being struck through.

The above objects and principles of the present invention will be described in more detail taken from the preferred embodiments below in conjunction with the accompanying drawings.

### BRIEF DESCRIPTION OF THE DRAWINGS

FIG. 1 shows a schematic diagram of a plasma sputtering target assembly according to the first embodiment of the present invention;

FIG. 2 shows a schematic diagram of the plasma sputtering target assembly according to the second embodiment of the present invention;

FIG. 3 shows a schematic diagram of the plasma sputtering target assembly according to the third embodiment of the present invention; and

FIG. 4 shows a flowchart of the manufacturing method for the plasma sputtering target assembly.

### DETAILED DESCRIPTION OF THE INVENTION

The preferred embodiments of the present invention will be described below with reference of the annexed drawings.

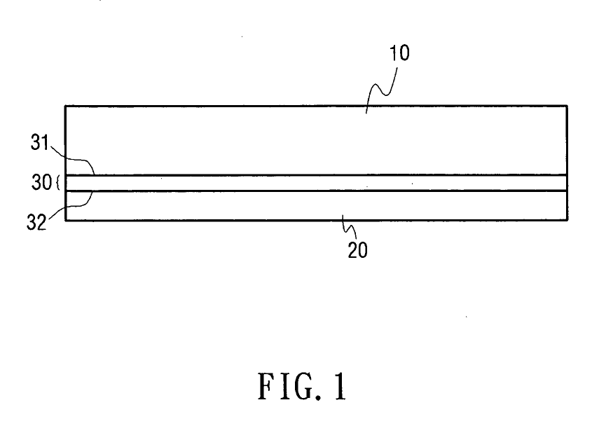

Referring to FIG. 1, a schematic diagram of a sputtering target assembly according to the first embodiment of the present invention is depicted therein. As shown, the sputtering target assembly comprises a target 10, a backplate 20, and a bonding layer 30. The bonding layer 30 has a plurality of particles 40 and a first side 31 and second side 32. The first side 31 of the bonding layer 30 is bonded with the target 10 and the second side 32 of bonding layer 30 is bond with the backplate 20. The meltability of the bonding layer 30 is lower then that of the target 10. In addition, the bonding layer 30 is composed of indium (In). In this embodiment, since the backplate 20 has been progressively heated to the meltability of indium before the backplate 20 and target 10 are assembled, the bonding layer 30 becomes in a liquid state from an originally solid state and sticky. At this time, particles 40 are provided on the bonding layer 30 before the target 10 is bonded onto the backplate 10 through the bonding layer 30. Since the bonding layer 30 has a composition different from that of the target 10 and since sputter yield of the particles 40 is different from that of the target 10, an interface between the bonding layer 30 and the target 10 is caused to be uneven when the target 10 is stuck through in the sputtering process, due to the different sputtering yields of the particle 40 and the target 10. When the target 10 is struck through, this uneven interface is exposed in plasma and thus an exceptional discharging phenomenon is caused, further bringing about an electric arc phenomenon. This electric arc phenomenon has an electromagnetic signal accompanying and the electromagnetic signal is used to forecast whether over-sputtering occurs on the target 10. If yes, the power supplied for the sputtering process is ceased.

For conventionally used targets, sputtering yields thereof range from 0.3 to 2.4. The material of the conventional target 10 maybe one of Indium-tin-oxide (ITO), copper (Cu), Iron (Fe), cobalt (Co), silicon (Si), titanium (Ti), zirconium (Zr), niobium (Nb), molybdenum (Mo), ruthenium (Ru), rhodium (Rh), palladium (Pd), Hafnium (Hf), tantalum (Ta), wolfram (W), rhenium (Re), osmium (Os), iridium (Ir), chromium (Cr), manganese (Mn), germanium (Ge), platinum (Pt), silver (Ag), Indium (In), gold (Au), or their mixture. The material of the particles 40 may be one of ITO, Cu, Fe, Co, Si, Ti, Zr, Nb, Mo, Ru, Rh, Pd, Hf, Ta, W, Re, Os, Ir, Cr, Mn, Ge, Pt, Ag, In, Au, or their mixture. Among them, Pd and Ta are the most suitable since they each have a sputtering yield having a maximum difference as compared to that of the target 10. This sputtering process has to be ceased before the backplate 20 is exposed to plasma, otherwise the target 10 should be struck through and thus a chamber for the sputtering process can be damaged. As related to the backplate 20, the material of the backplate 20 may be one of ITO, Cu, Fe, Co, Si, Ti, Zr, Nb, Mo, Ru, Rh, Pd, Hf, Ta, W, Re, Os, Ir, Cr, Mn, Ge, Pt, Ag, aluminum (Al), nickel (Nl), Au, or their mixture. Since the bonding layer 30 is first exposed to the plasma when the target 10 is almost over-sputtered, an exceptional discharging phenomenon is caused when the target is struck through. By detecting the discharging phenomenon, whether the target is almost over-sputtered may be forecasted.

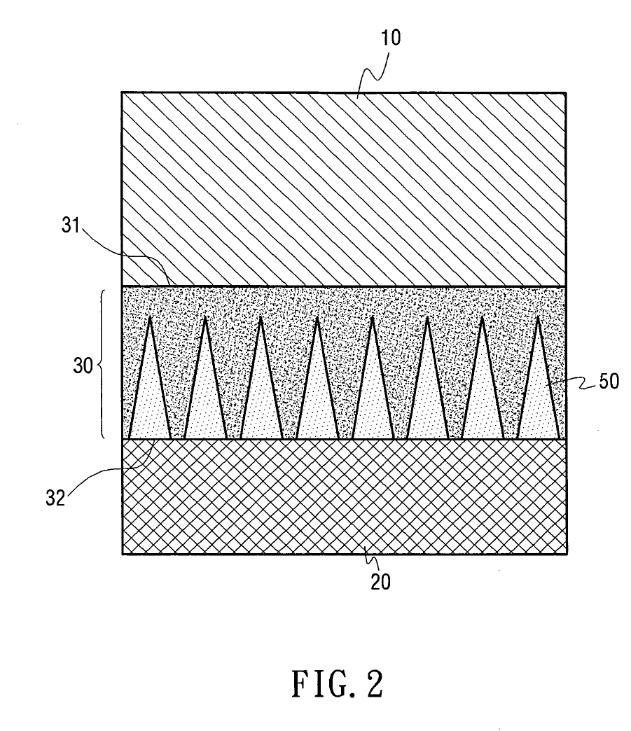

Referring to FIG. 2, the plasma sputtering target assembly according to the second embodiment of the present invention is diacritically depicted. As shown, the plasma sputtering target assembly comprises a target 10, a backplate 20 having a plurality of protrusions 50, and a bonding layer 30, which has a first side 31 bonded with the target 10 and second side 32 bonded with the backplate 20. This embodiment is identical to the first embodiment except that a plurality of protrusions 50 is formed on the bonding layer, compared with the first embodiment where the particles 40 are provided on the bonding layer, the bonding layer 30 is greater than or equal to the protrusions 50 in altitude. More specifically, how big and sharp of each of the protrusions 50 are determined so that an exceptional discharging phenomenon may be caused when they are exposed to a plasma and the target 10 is struck through. By detecting the discharging phenomenon, whether the target 10 is almost over-sputtered may be forecasted. As such, the target 10 may be prevented from being over-sputtered. To fabricate the plurality of protrusions 50, a processing method such as casting and mechanical processing (lathing and milling) may be utilized, so the plurality of protrusions 50 might be integrated with the backplate 20. The protrusions 50 and the backplate 20 may make from the same material. In addition, the protrusions 50 may each be in any form of an awl shape and the materials may be one of ITO, Cu, Fe, Co, Si, Ti, Zr, Nb, Mo, Ru, Rh, Pd, Hf, Ta, W, Re, Os, Tr, Cr, Mn, Ge, Pt, Ag, In, Au, or their mixture.

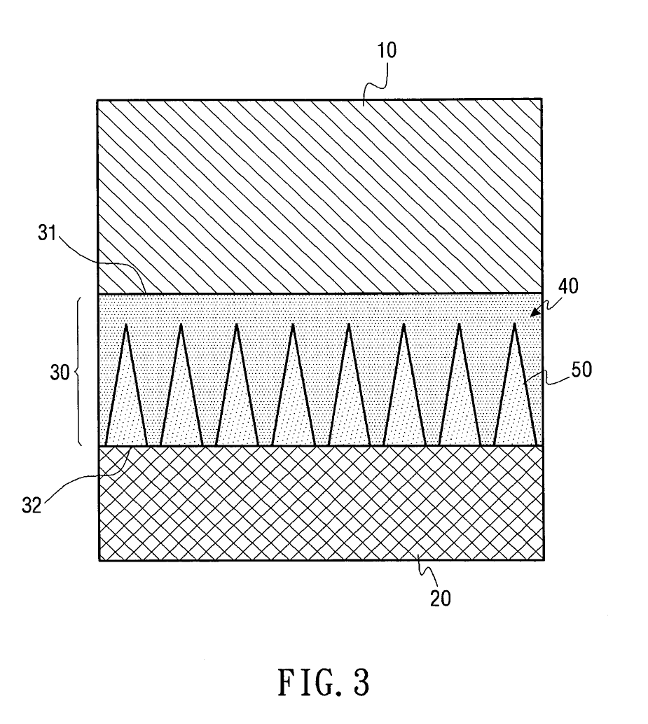

Referring to FIG. 3, the plasma sputtering target assembly according to the third embodiment of the present invention is diacritically depicted. As shown, the plasma sputtering target assembly comprises a target 10, a backplate 20 having a plurality of protrusions 50, and a bonding layer 30 having a plurality of particles 40, which has a first side 31 and second side 32. The materials used on the particles 40 and the target 10 are different. The first side 31 of the bonding layer 30 is bonded with the target 10 and the second side 32 of the bonding layer 30 is bonded with backplate 20. In this embodiment, the structure and material are a new combination of the first embodiment and the second embodiment, wherein the plurality of protrusions 50, the backplate 20, and the target 10 are using different material.

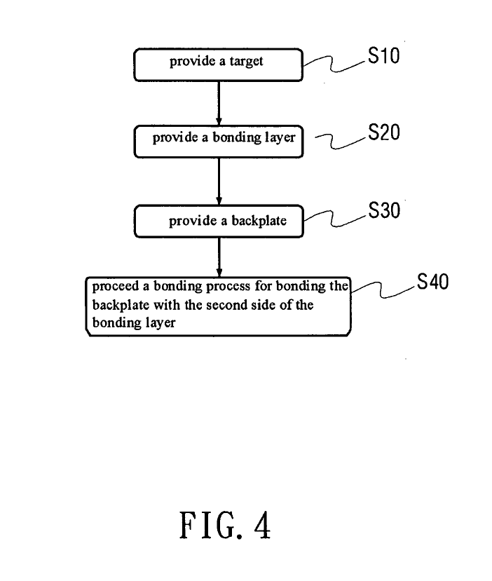

Referring to FIG. 4, a flowchart of the manufacturing method for the plasma sputtering target assembly according to the first embodiment of the present invention is illustrated therein. The manufacturing method comprises the steps of providing a target (S10), providing a bonding layer having a plurality of particles and having a first side bonded with the target and a second side (S20), providing a backplate which has a plurality of protrusions integrated with the backplate and the protrusions are not greater than the bonding layer in altitude (S30), proceeding a bonding process for bonding the backplate with the second side of the bonding layer (S40).

As described above, the target may be exposed to the plasma when the sputtering process is conducted and the power supplied for the sputtering process may be immediately ceased upon the exceptional discharging phenomenon occurring. As such, the target may be prevented from being struck through and thus from being over-sputtered.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A plasma sputtering target assembly, comprising:
a target;
a bonding layer having a plurality of particles and having a first side bonded with said target and a second side; and
a backplate bonded with said second side of said bonding layer.

2. The plasma sputtering target assembly according to claim 1, wherein said target is selected from the group consisting of Indium-tin-oxide (ITO), copper (Cu), Iron (Fe), cobalt (Co), silicon (Si), titanium (Ti), zirconium (Zr), niobium (Nb), molybdenum (Mo), ruthenium (Ru), rhodium (Rh), palladium (Pd), Hafnium (Hf), tantalum (Ta), wolfram (W), rhenium (Re), osmium (Os), iridium (fr), chromium (Cr), manganese (Mn), germanium (Ge), platinum (Pt), silver (Ag), Indium (In), gold (Au), and a mixture thereof.

3. The plasma sputtering target assembly according to claim 1, wherein said bonding layer has a lower meltability than that of said target.

4. The plasma sputtering target assembly according to claim 1, wherein said particles and said target are made of different materials.

5. The plasma sputtering target assembly according to claim 1, wherein said particle is selected from the group consisting of ITO, Cu, Fe, Co, Si, Ti, Zr, Nb, Mo, Ru, Rh, Pd, Hf, Ta, W, Re, Os, Ir, Cr. Mn, Ge, Pt, Ag, In, Au, and a mixture thereof.

6. A plasma sputtering target assembly, comprising:
a target;
a bonding layer having a first side bonded with said target and a second side; and
a backplate having a plurality of protrusions and bonded with said second side of said bonding layer.

7. The plasma sputtering target assembly according to claim 6, wherein said bonding layer includes particles.

8. The plasma sputtering target assembly according to claim 6, wherein said target is selected from the group consisting of ITO, Cu, Fe, Co, Si, Ti, Zr, Nb, Mo, Ru, Rh, Pd, Hf, Ta, W, Re, Os, Ir, Cr, Mn, Ge, Pt, Ag, In, Au, and a mixture thereof.

9. The plasma sputtering target assembly according to claim 6, wherein said bonding layer has a lower meltability than that of said target.

10. The plasma sputtering target assembly according to claim 7, wherein said particles and said target are made of different materials.

11. The plasma sputtering target assembly according to claim 7, wherein said particles is selected from the group consisting of ITO, Cu, Fe, Co, Si, Ti, Zr, Nb, Mo, Ru, Rh, Pd, Hf, Ta, W, Re, Os, Ir, Cr, Mn, Ge, Pt, Ag, In, Au, and a mixture thereof.

12. The plasma sputtering target assembly according to claim 6, wherein said protrusions and said backplate are made of the same material.

13. The plasma sputtering target assembly according to claim 6, wherein said protrusions is an awl shape.

14. The plasma sputtering target assembly according to claim 6, wherein said protrusions and said backplate are integrated together.

15. The plasma sputtering target assembly according to claim 6, wherein said protrusions, said backplate, and said target are made of different materials.

16. The plasma sputtering target assembly according to claim 6, wherein said protrusions is selected from the group consisting of ITO, Cu, Fe, Co, Si, Ti, Zr, Nb, Mo, Ru, Rh, Pd, Hf, Ta, W, Re, Os, Tr, Cr, Mn, Ge, Pt, Ag, In, Au, and a mixture thereof .

17. A manufacturing method for a plasma sputtering target assembly, comprising the steps of:
providing a target;
providing a bonding layer having a plurality of particles and having a first side bonded with the target and a second side;
providing a backplate, wherein a plurality of protrusions integrated with said backplate and said protrusions are not greater than said bonding layer in altitude; and
proceeding a bonding process for bonding the backplate with the second side of the bonding layer.

18. The manufacturing method for a plasma sputtering target assembly according to claim 17, wherein said target is selected from the group consisting of ITO, Cu, Fe, Co, Si, Ti, Zr, Nb, Mo, Ru, Rh, Pd, Hf, Ta, W, Re, Os, Ir, Cr, Mn, Ge, Pt, Ag, In, Au, and a mixture thereof.

19. The manufacturing method for a plasma sputtering target assembly according to claim 17, wherein said bonding layer has a lower meltability than that of said target.

20. The manufacturing method for a plasma sputtering target assembly according to claim 17, wherein said particles and said target are made of different materials.

21. The manufacturing method for a plasma sputtering target assembly according to claim 17, wherein said particle is selected from the group consisting of ITO, Cu, Fe, Co, Si, Ti, Zr, Nb, Mo, Ru, Rh, Pd, Hf, Ta, W, Re, Os, Ir, Cr, Mn, Ge, Pt, Ag, In, Au, and a mixture thereof.

22. The manufacturing method for a plasma sputtering target assembly according to claim 17, wherein said protrusions and said backplate are made of the same material.

23. The manufacturing method for a plasma sputtering target assembly according to claim 17, wherein said protrusions is an awl shape.

24. The manufacturing method for a plasma sputtering target assembly according to claim 17, wherein said protrusions and said backplate are integrated together.

25. The manufacturing method for a plasma sputtering target assembly according to claim 17, wherein said protrusions, said backplate, and said target are made of different materials.

26. The manufacturing method for a plasma sputtering target assembly according to claim 17, wherein said protrusions is selected from the group consisting of ITO, Cu, Fe, Co, Si, Ti, Zr, Nb, Mo, Ru, Rh, Pd, Hf, Ta, W, Re, Os, Tr, Cr, Mn, Ge, Pt, Ag, In, Au, and a mixture thereof.
